(19) United States
(12) Patent Application Publication
(10) Pub. No.: US 2025/0133689 A1
(43) Pub. Date: Apr. 24, 2025

(54) CONTROL APPARATUS AND COOLING METHOD OF CONTROL APPARATUS

(71) Applicant: KABUSHIKI KAISHA YASKAWA DENKI, Kitakyushu-shi (JP)

(72) Inventor: Yoshihiro HIGASHI, Fukuoka (JP)

(73) Assignee: KABUSHIKI KAISHA YASKAWA DENKI, Kitakyushu-shi (JP)

(21) Appl. No.: 18/824,908

(22) Filed: Sep. 5, 2024

(30) Foreign Application Priority Data
Oct. 20, 2023 (JP) 2023-181395

(51) Int. Cl. H05K 7/20

(52) U.S. Cl. CPC H05K 7/20172

(57) ABSTRACT

A control apparatus includes a first chamber into which air is configured to flow from an outside of the control apparatus and which has a cross-sectional area of flow, a second chamber which communicates with the first chamber such that the air flows from the first chamber to the second chamber and which has a cross-sectional area of flow smaller than the cross-sectional area of flow of the first chamber, and a third chamber which communicates with the second chamber such that the air flows from the second chamber to the third chamber and which has a cross-sectional area of flow smaller than the cross-sectional area of flow of the second chamber.

### CROSS-REFERENCE TO RELATED APPLICATIONS

The present application claims priority under 35 U.S.C. § 119 to Japanese Patent Application No. 2023-181395, filed Oct. 20, 2023. The contents of this application are incorporated herein by reference in their entirety.

### BACKGROUND OF THE INVENTION

### Field of the Invention

The disclosed embodiment relates to a control apparatus and a cooling method of a control apparatus.

### Discussion of The Background

Japanese Patent Application Laid-Open No. H02-168697 discloses a cooling device for an electronic device in which heating elements and fins are arranged in series in two stages, front and rear, and a ventilation duct system is configured in which the cross-sectional area of the ventilation duct in a direction orthogonal to the flow direction of cooling air is different and the cross-sectional area decreases toward the downstream side of the cooling air.

### SUMMARY OF THE INVENTION

According to one aspect of the present invention, a control apparatus includes a first chamber into which air is configured to flow from an outside of the control apparatus and which has a cross-sectional area of flow, a second chamber which communicates with the first chamber such that the air flows from the first chamber to the second chamber and which has a cross-sectional area of flow smaller than the cross-sectional area of flow of the first chamber, and a third chamber which communicates with the second chamber such that the air flows from the second chamber to the third chamber and which has a cross-sectional area of flow smaller than the cross-sectional area of flow of the second chamber.

According to another aspect of the present invention, a cooling method of a control apparatus includes letting air flow from an outside of the control apparatus into a first chamber which has a cross-sectional area of flow, letting the air flow from the first chamber to a second chamber which has a cross-sectional area of flow smaller than the cross-sectional area of flow of the first chamber, and letting the air flow from the second chamber to a third chamber which has a cross-sectional area of flow smaller than the cross-sectional area of flow of the second chamber.

### BRIEF DESCRIPTION OF DRAWINGS

A more complete appreciation of the present disclosure and many of the attendant advantages thereof will be readily obtained as the same becomes better understood by reference to the following detailed description when considered in connection with the accompanying drawings.

FIG. 1 is a perspective view showing an example of the overall configuration of a control apparatus according to the present embodiment.

FIG. 2 is a perspective view showing an example of a state in which a front surface panel of the control apparatus according to the present embodiment is opened.

FIG. 3 is a perspective view showing an example of a state in which each panel of the housing of the control apparatus according to the embodiment is removed.

FIG. 4 is a perspective view showing an example of an external configuration of an air duct.

FIG. 5 is an exploded perspective view showing an example of the internal structure of the air duct.

FIG. 6 is a sectional perspective view corresponding to a section taken along line VI-VI in FIG. 5.

FIG. 7 is a perspective view showing an example of an external configuration of an air duct in a state where an exhaust member is removed.

FIG. 8 is a perspective view showing an example of an external configuration of an air duct in a state where an exhaust member is attached.

FIG. 9 is a conceptual diagram showing an example of the size relationship between each of the opening cross-sectional areas of each of the chambers and openings constituting the air duct.

FIG. 10 is a perspective view showing an example of a case where the servo unit is replaced from above.

FIG. 11 is a perspective view showing an example of a case where the servo unit is replaced from the front side.

FIG. 12 is a perspective view showing an example of a case where the servo unit is replaced from the front side.

### DESCRIPTION OF EMBODIMENTS

Hereinafter, embodiments will be described with reference to the drawings. In the embodiment, for convenience of description of the configuration of the control apparatus and the like, directions such as up, down, left, right, front, and rear are appropriately used, but these directions do not limit the orientation or arrangement of each configuration of the control apparatus and the like. In the embodiment, directions such as up, down, left, right, front, and rear correspond to directions of arrows shown in the drawings.

### 1. Overall Configuration of Control Apparatus

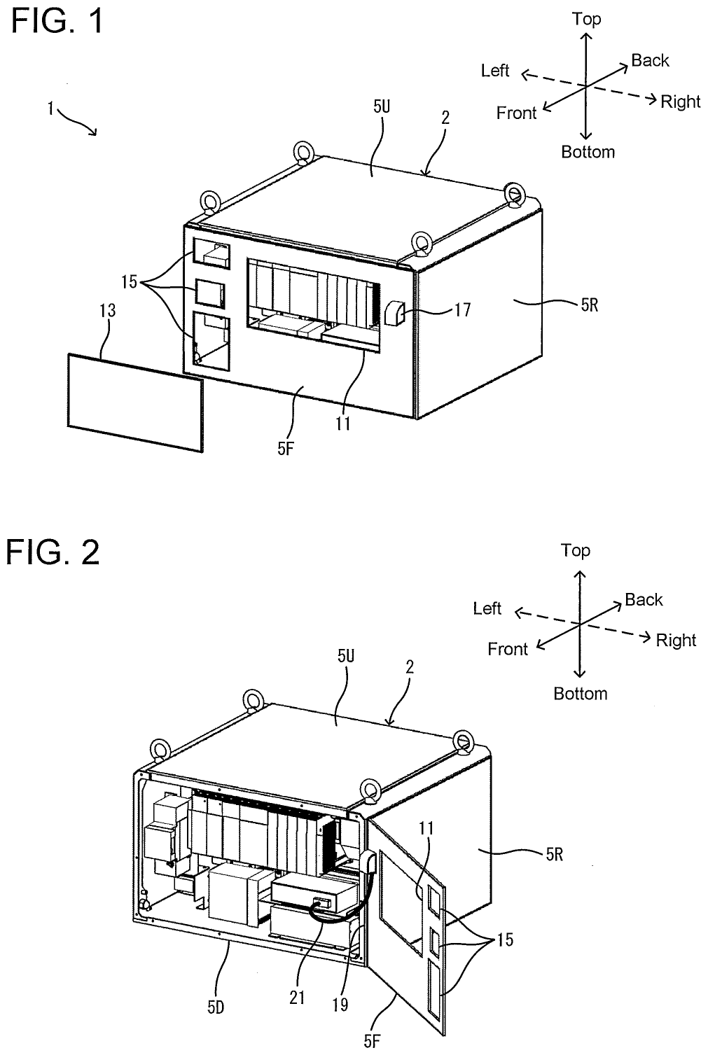

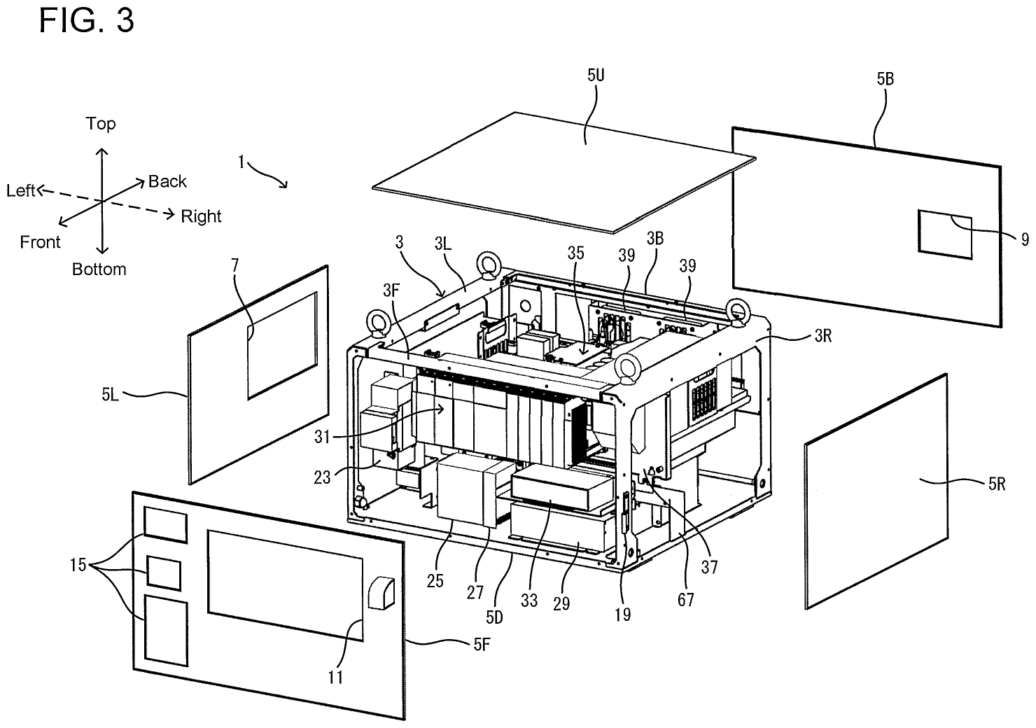

An example of the overall configuration of the control apparatus according to the embodiment will be described with reference to FIGS. 1 to 3. FIG. 1 is a perspective view showing an example of an overall configuration of a control apparatus according to an embodiment, and FIG. 2 a perspective view showing an example of a state in which a front panel of the control apparatus according to an embodiment is opened. FIG. 3 is a perspective view showing an example of a state in which each panel of the housing of the control apparatus according to the embodiment is removed.

The control apparatus 1 controls a control target such as a motor or an industrial machine (robot or the like) driven by a motor. As shown in FIGS. 1 to 3, the control apparatus 1 includes a frame 3 and a plurality of panels 5. The plurality of panels 5 include a front surface panel 5F, a back surface panel 5B, a left surface panel 5L, a right surface panel 5R, an upper surface panel 5U, and a bottom surface panel 5D.

As shown in FIG. 3, the frame 3 constitutes a framework of the housing 2. The frame 3 includes a left side frame portion 3L and a right side frame portion 3R which are substantially U-shaped and open on the lower side, and a front side frame portion 3F and a back side frame portion 3B which are substantially rod-shaped and connect the upper end of the left side frame portion 3L and the upper end of the right side frame portion 3R. The left side frame portion 3L and the right side frame portion 3R are provided upright at four corners of the bottom surface panel 5D.

The front surface panel 5F is fixed to the front end portions of the front side frame portion 3F, the left side frame portion 3L, and the right side frame portion 3R by, for example, screws or the like. The back surface panel 5B is fixed to the rear end portions of the back side frame portion 3B, the left side frame portion 3L, and the right side frame portion 3R by, for example, screws or the like. The left surface panel 5L is fixed to the left side frame portion 3L by, for example, a screw, and the right surface panel 5R is fixed to the right side frame portion 3R by, for example, a screw. The upper surface panel 5U is fixed to the upper end portions of the front side frame portion 3F, the back side frame portion 3B, the left side frame portion 3L, and the right side frame portion 3R by, for example, screws. The lower end portions of the left side frame portion 3L and the right side frame portion 3R are fixed to the bottom surface panel 5D by, for example, screws or the like. The panels 5 are attached to the frame 3 respectively, and thus the housing 2 having a substantially rectangular parallelepiped shape is formed. Each panel 5 is adjacent to an adjacent panel 5 at a substantially right angle.

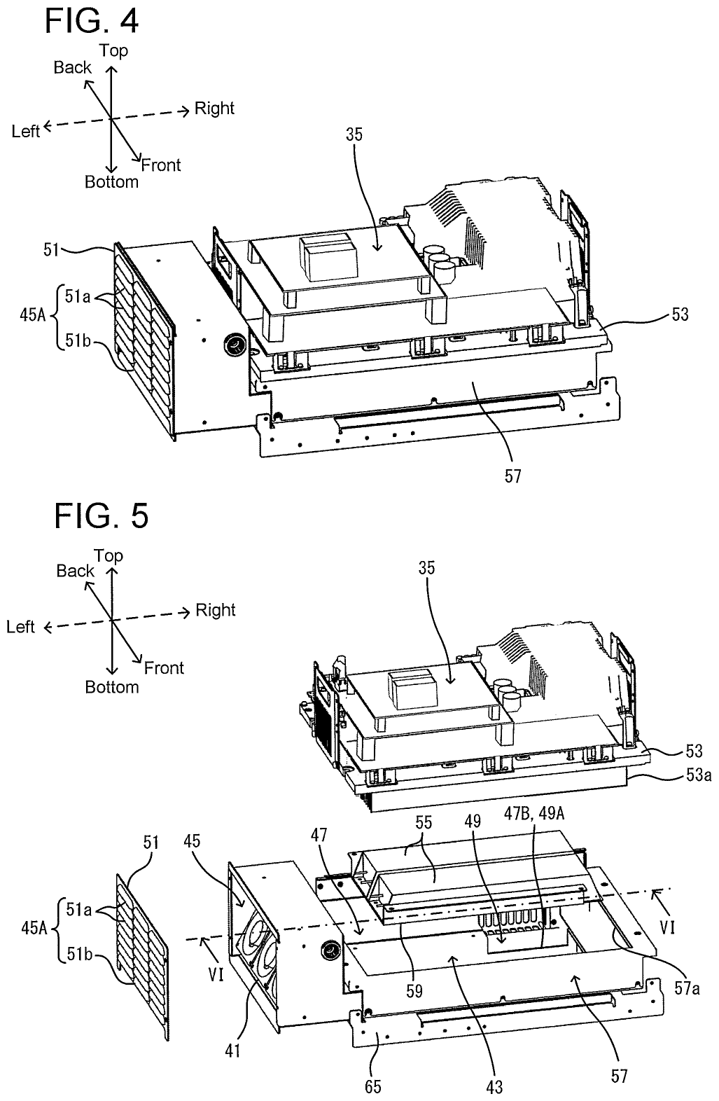

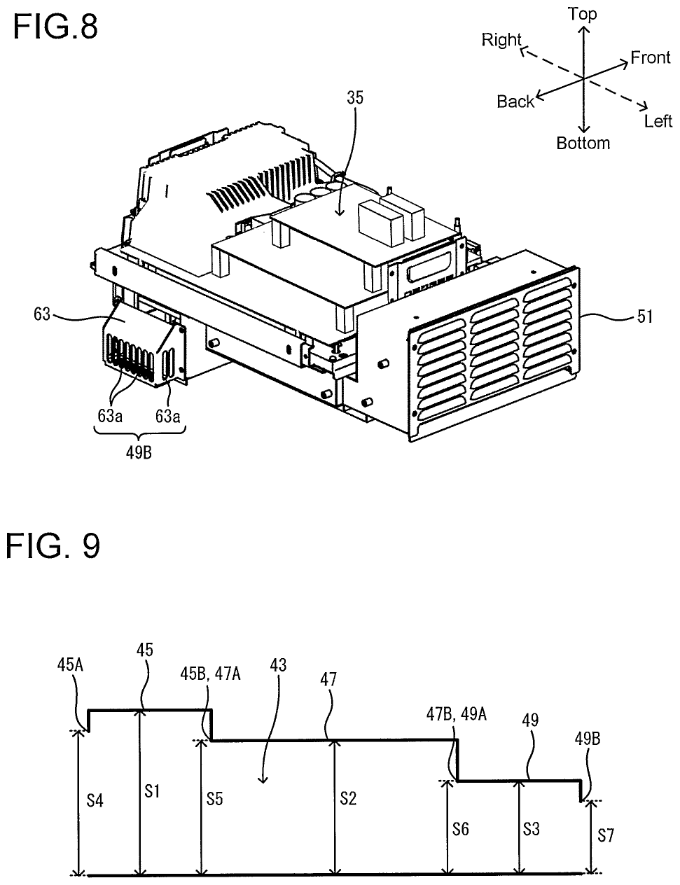

As shown in FIG. 3, a substantially rectangular opening 7 is formed in the left surface panel 5L. An intake member 51 (see FIG. 4), which will be described later, is disposed in the opening 7. A substantially rectangular opening 9 is formed in the back surface panel 5B. An exhaust member 63 (see FIG. 8) to be described later is disposed in the opening 9. The left surface panel 5L (an example of a wall portion) and the back panel side wall (an example of a wall portion) are adjacent to each other at a substantially right angle.

As shown in FIG. 1, a substantially quadrangular opening 11 is formed in a substantially central portion of the front surface panel 5F. A cover 13 is attached to and detached from the opening 11 by, for example, screws. The opening 11 is closed when the cover 13 is attached, and is opened when the cover 13 is removed. By removing the cover 13, the internal devices of the control apparatus 1 can be accessed from the front through the opening 11 without removing or opening the front surface panel 5F. A plurality of openings 15 in which various connectors (not illustrated) are disposed are formed on, for example, the left side of the front surface panel 5F. A connector 17 is provided on, for example, the right side of the front surface panel 5F to protrude forward. A cable for connecting a terminal device (also referred to as a pendant) carried by an operator during maintenance or the like is connected to the connector 17 from, for example, the lower side.

As shown in FIGS. 2 and 3, a hinge 19 is provided at the front end of the right side frame portion 3R. The hinge 19 is configured to allow the front surface panel 5F to be attached and detached. As shown in FIG. 2, the front surface panel 5F can be rotated about the hinge 19 to open the front of the housing 2, or as shown in FIG. 3, the front surface panel 5F can be removed to open the front of the housing 2. As shown in FIG. 2, the connector 17 is connected to the internal device via a cable 21 inside the front surface panel 5F. When the maintenance work is performed by connecting the terminals to the connectors 17, the front surface panel 5F is opened by rotating it like a door as shown in FIG. 2, so that the work can be performed while the connection of the cables 21 is maintained.

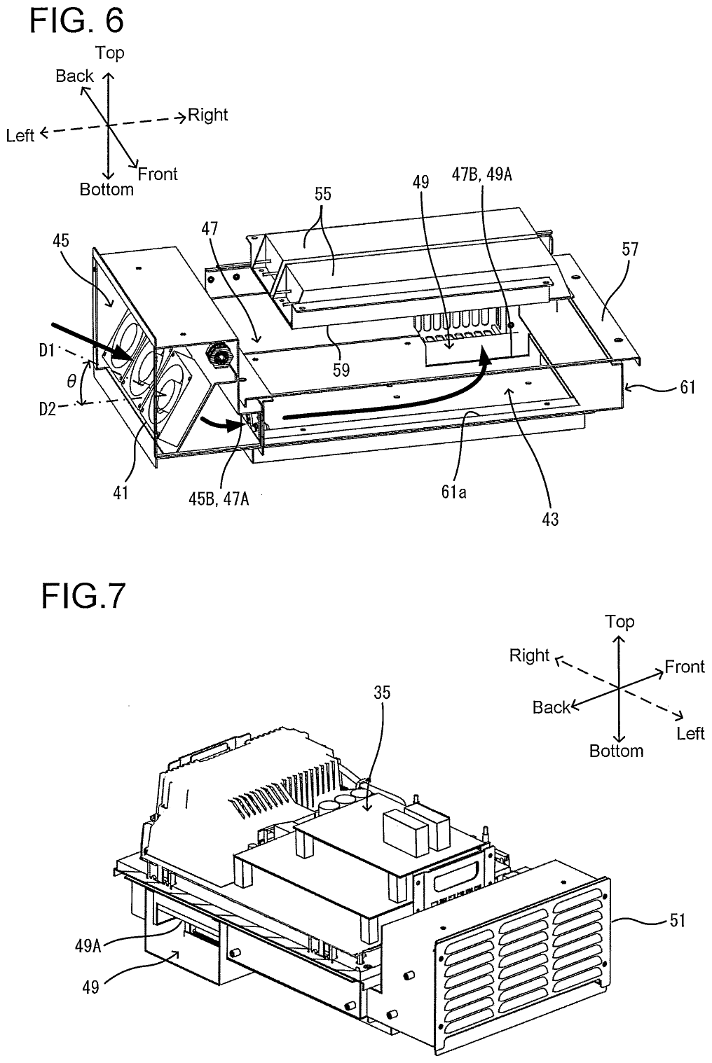

As shown in FIG. 3, various electric components are disposed in the internal space of the housing 2. For example, the breaker 23, the electromagnetic switch 25, the hub 27, the power supply unit 29, the first control unit 31, the second control unit 33, the servo unit 35, and the like are disposed. The internal space of the housing 2 is partitioned into three layers of spaces in the vertical direction. In the lower space, the breaker 23, the electromagnetic switch 25, the hub 27, the power supply unit 29, the second control unit 33, and the like are disposed. In the space of the middle layer, an air duct 43 through which air is passed by the cooling fan 41 is disposed (see FIGS. 5 and 6). The servo unit 35 and the like are disposed in the space of the upper layer. The first control unit 31 is supported by a plate-shaped support plate 37. The support plate 37 divides the upper side of the internal space of the housing 2 into a front space and a rear space. The first control unit 31 is disposed in a space in front of the support plate 37, and the above-described air duct 43, the servo unit 35, and the like are disposed in a space behind the support plate 37.

As shown in FIG. 3, a circulation fan 39 (an example of a second fan) is provided behind the servo unit 35. In the example shown in FIG. 3, two circulation fans 39 are installed, but the number of circulation fans 39 may be other than two. The circulation fan 39 is disposed in the internal space of the housing 2 other than the air duct 43, and circulates the air in the internal space other than the air duct 43. No opening is provided at a position corresponding to the circulation fan 39 on the back surface panel 5B, and the circulation fan 39 circulates air without taking in outside air. Specifically, the air discharged from the circulation fan 39 passes around the servo unit 35, advances to the front side, and collides with the support plate 37. The air that has collided with the support plate 37 moves to the right side and flows into the space in the lower layer through the clearance between the servo unit 35 and the 5R of the right panel. The air that has flowed into the lower space circulates in the lower space, moves upward at the rear of the internal space, and is sucked into the circulation fan 39. By circulating the air inside the housing 2 in this way, it is possible to disperse and cool the heat that has accumulated in the upper portion of the internal space due to the heat generated by the electrical components such as the first control unit 31 and the servo unit 35.

The configuration of the control apparatus 1 described above is an example, and is not limited to the above-described content. For example, the internal space of the housing 2 may be configured as a single layer without being partitioned into a plurality of layers, or may be partitioned into a plurality of layers other than three layers. Further, an opening may be formed in a position corresponding to the circulation fan 39 of the back surface panel 5B, and the outside air may be taken in and ventilated by the circulation fan 39.

### 2. Configuration of Air Duct

An example of the configuration of the air duct 43 will be described with reference to FIGS. 4 to 9. FIG. 4 is a perspective view showing an example of the external configuration of the air duct 43, FIG. 5 is an exploded perspective view showing an example of the internal configuration of the air duct 43, FIG. 6 is a sectional perspective view corresponding to a section taken along line VI-VI in FIG. 5, FIG. 7 is a perspective view showing an example of the external configuration of the air duct 43 with the exhaust member 63 removed, FIG. 8 is a perspective view showing an example of the external configuration of the air duct 43 with the exhaust member 63 attached, and FIG. 9 is a conceptual diagram showing an example of the size relationship of the opening cross-sectional areas of the chambers and openings constituting the air duct 43.

As shown in FIGS. 5 and 6, an air duct 43, which is a space through which the cooling fan 41 blows outside air, is provided in the middle layer of the internal space of the housing 2. The air duct 43 includes a first chamber 45, a second chamber 47, and a third chamber 49. The first chamber 45, the second chamber 47, and the third chamber 49 are arranged in the order of the first chamber 45, the second chamber 47, and the third chamber 49 from the upstream side to the downstream side in the airflow direction (indicated by a thick arrow in FIG. 6) of the air duct 43.

The first chamber 45 houses a cooling fan 41 (an example of a first fan) that allows air to flow into the second chamber 47, and air from the outside flows into the first chamber 45. In the example shown in FIGS. 5 and 6, three cooling fans 41 are installed, but the number of cooling fans 41 may be other than three. The first chamber 45 includes a first intake port 45A (see FIGS. 4 and 5) for sucking air from the outside on the left side, and a first exhaust port 45B (see FIG. 6) for discharging air to the second chamber 47 on the right side. As shown in FIGS. 4 and 5, the first intake port 45A is constituted by a plurality of louvers 51a and a lower opening 51b provided in the intake member 51 provided at the entrance of the first chamber 45. The opening cross-sectional area S5 of the first exhaust port 45B is smaller than the opening cross-sectional area S4 of the first intake port 45A. In the present embodiment, the “opening cross-sectional area” refers to the area of a cross section of the opening orthogonal to the airflow direction. As shown in FIG. 6, the cooling fans 41 are disposed in the first chamber 45 so as to be inclined by a predetermined angle θ with respect to a direction D2 perpendicular to the left surface panel 5L (an example of a wall portion) of the housing 2 on which the first air intake port 45A is provided, such that the rotation axis direction D1 faces the first exhaust port 45B (second intake port 47A). The angle θ is set such that the rotation axis direction D1 passes through the range of the opening cross-sectional area S5 of the first exhaust port 45B (second intake port 47A), for example.

The second chamber 47 communicates with the first chamber 45 and houses components to be cooled. In the present embodiment, “communication” means that two chambers are connected to each other so that air can freely flow therethrough, and the two chambers may be directly connected to each other or may be indirectly connected to each other with another space interposed therebetween. As shown in FIG. 5, the components to be cooled by the second chamber 47 are the fin 53a of the heat sink 53 on which the servo unit 35 is disposed, and the regenerative resistor 55. The servo unit 35 includes electric components that generate heat, such as a power semiconductor element and a capacitor, and is cooled via the heat sink 53. In the example shown in FIGS. 5 and 6, two substantially rectangular parallelepiped regenerative resistors 55 are provided, but the number of the regenerative resistors 55 may be other than two. Further, components to be cooled other than the above may be accommodated in the second chamber 47. As shown in FIG. 6, the second chamber 47 includes a second intake port 47A for sucking air from the first chamber 45 on the left side, and a second exhaust port 47B for discharging air to the third chamber 49 on the rear side. The second chamber 47 forms a substantially L-shaped air duct in which the airflow direction is changed from the right direction to the rear direction. The second intake port 47A of the second chamber 47 is common to the first exhaust port 45B of the first chamber 45, and both of them are the opening cross-sectional area S5. The opening cross-sectional area S5 of the second exhaust port 47B is smaller than the opening cross-sectional area S5 of the second intake port 47A. The first chamber 45 and the second chamber 47 are directly connected to each other without another space interposed between the first exhaust port 45B and the second intake port 47A, but may be indirectly connected to each other with another space interposed between the first exhaust port 45B and the second intake port 47A.

As shown in FIGS. 4 to 6, the heat sink 53 on which the servo unit 35 is mounted is supported by a base member 57 (an example of a support member), and the regenerative resistor 55 is supported by base members 59, 61 (an example of a support member). The regenerative resistor 55 is placed on the upper portion of the base member 59. As shown in FIG. 6, the base member 59 is fixed to the base member 61 to close an opening 61a of a bottom portion of the base member 61 formed in a box shape. The base member 57 is placed to cover the upper portion of the base member 61. As shown in FIG. 5, the opening 57a of the base member 57 is closed by the heat sink 53. The base members 57, 59, 61 are formed by processing a sheet metal, for example. The second chamber 47 accommodates the fin 53a of the heat sink 53 and the regenerative resistor 55 which are disposed to face each other. In the second chamber 47, a space sandwiched between a plurality of base members 57, 59, 61 supporting the servo unit 35 (an example of an electric component) and the regenerative resistor 55 (an example of an electric component), and the fin 53a and the regenerative resistor 55 arranged to face each other forms an air duct. An opening cross-sectional area (an example of “a cross-sectional area of flow of the second chamber”) S2 orthogonal to the airflow direction of the air in the air duct in the second chamber 47 is smaller than an opening cross-sectional area (an example of “a cross-sectional area of flow of the first chamber”) S1 orthogonal to the airflow direction of the air in the first chamber 45.

The third chamber 49 communicates with the second chamber 47 and discharges air to the outside. As shown in FIGS. 7 and 8, the third chamber 49 has a third intake port 49A for sucking air from the second chamber 47 on the front side, and third exhaust ports 49B for discharging air to the outside on the rear side and both the left and right sides. As shown in FIG. 8, the third exhaust port 49B is constituted by a plurality of openings 63a provided in an exhaust member 63 provided at the outlet of the third chamber 49. The third intake port 49A of the third chamber 49 is common to the second exhaust port 47B of the second chamber 47, and both of them are the opening cross-sectional area S6. The opening cross-sectional area S7 of the third exhaust port 49B is smaller than the opening cross-sectional area S6 of the third intake port 49A. The second chamber 47 and the third chamber 49 are directly connected to each other without another space interposed between the second exhaust port 47B and the third intake port 49A, but may be indirectly connected to each other with another space interposed between the second exhaust port 47B and the third intake port 49A. The opening cross-sectional area (an example of “a cross-sectional area of flow of the third chamber”) S3 orthogonal to the airflow direction in the third chamber 49 is smaller than the opening cross-sectional area S2 orthogonal to the airflow direction in the second chamber 47. FIG. 9 conceptually shows the size relationship between the opening cross-sectional areas of the chambers and openings constituting the air duct 43. As shown in FIG. 9, the opening cross-sectional area S2 of the second chamber 47 is smaller than the opening cross-sectional area S1 of the first chamber 45, and the opening cross-sectional area S3 of the third chamber 49 is smaller than the opening cross-sectional area S2 of the second chamber 47. The opening cross-sectional area S5 of the first exhaust port 45B (second intake port 47A) is smaller than the opening cross-sectional area S4 of the first intake port 45A. The opening cross-sectional area S6 of the second exhaust port 47B (third intake port 49A) is smaller than the opening cross-sectional area S5 of the second intake port 47A (first exhaust port 45B). The opening cross-sectional area S7 of the third exhaust port 49B is smaller than the opening cross-sectional area S6 of the third intake port 49A (second exhaust port S6). The opening cross-sectional area S2 of the second chamber 47 is substantially equal to the opening cross-sectional area S5 of the first exhaust port 45B (second intake port 47A), and the opening cross-sectional area S3 of the third chamber 49 is substantially equal to the opening cross-sectional area S6 of the second exhaust port 47B (third intake port 49A).

For example, when the opening cross-sectional area S5 is 90% of the opening cross-sectional area S4, the opening cross-sectional area S6 is 70% of the opening cross-sectional area S5, and the opening cross-sectional area S7 is 80% of the opening cross-sectional area S6, the opening cross-sectional area S7 is about 50% of the opening cross-sectional area S4. That is, the reduction ratio of the opening cross-sectional area from the first intake port 45A to the third exhaust port 49B in the entire air duct 43 is about 50%.

The configuration of the air duct 43 described above is an example, and the present invention is not limited to the above description. For example, in the above description, the cooling fan 41 is provided in the first chamber 45 to blow out air to thereby allow the air to flow into the second chamber 47, but the cooling fan 41 may be disposed in the third chamber 49 to suck in air to thereby cause the air to flow into the second chamber 47. Further, the cooling fan 41 may be provided in both the first chamber 45 and the third chamber 49. In the above description, the air duct 43 is formed in a substantially L-shape, and the air is sucked from the left side of the housing 2 and discharged from the rear side of the housing 2. Further, the air duct 43 may be formed in a linear shape, and the air may be sucked from the left side of the housing 2 and discharged from the right side, or the air may be sucked from the right side of the housing 2 and discharged from the left side.

### 3. Method of Replacing Servo Unit

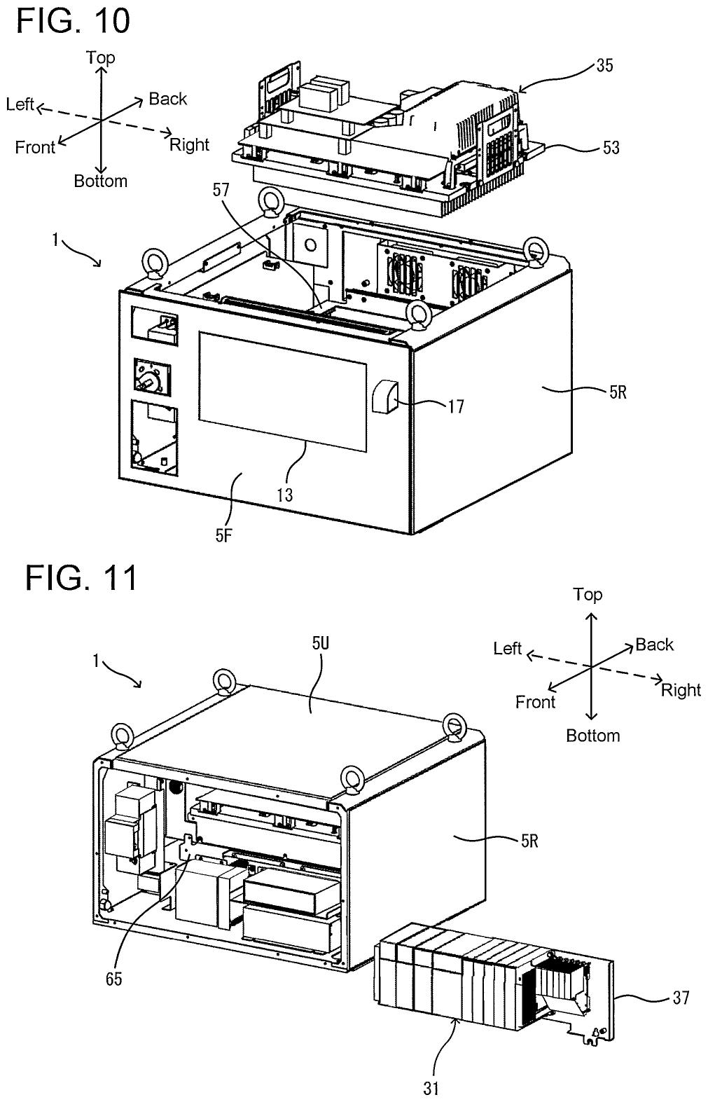

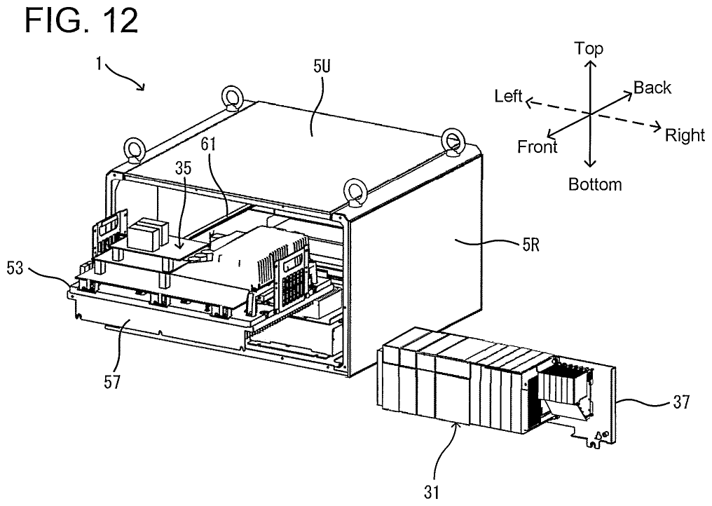

A method of replacing the servo unit 35 will be described with reference to FIGS. 10 to 12. FIG. 10 is a perspective view showing an example of the case where the servo unit 35 is replaced from above, and FIGS. 11 and 12 are perspective views showing an example of the case where the servo unit 35 is replaced from the front.

In the example shown in FIG. 10, first, the upper surface panel 5U of the housing 2 is removed. Next, the servo unit 35 is removed from the base member 57 together with the heat sink 53. The heat sink 53 is fixed to the upper portion of the base member 57 by, for example, screws or the like, and can be removed from above by releasing the fixation. As described above, the servo unit 35 can be replaced from above without removing the front surface panel 5F, the back surface panel 5B, the left surface panel 5L, the right surface panel 5R, and the like of the housing 2.

In the example shown in FIG. 11, the front surface panel 5F of the housing 2 is first removed. The front surface panel 5F may be opened by rotating the front surface panel by the hinge 19. Next, the first control unit 31 is removed from the housing 2 together with the support plate 37. The support plate 37 is fixed to a base member 65 fixed to the bottom surface panel 5D by, for example, screws, and can be removed from the front by releasing the fixation. Next, as shown in FIG. 12, the servo unit 35 is removed from the base member 61 together with the heat sink 53 and the base member 57. The base member 57 is fixed to the upper portion of the base member 61 by, for example, a screw or the like, and can be removed from the front by releasing the fixation to slide in the front-rear direction with respect to the base member 61. As described above, the servo unit 35 can be replaced from the front without removing the upper surface panel 5U, the back surface panel 5B, the left surface panel 5L, the right surface panel 5R, and the like of the housing 2. Note that the upper surface panel 5U may be removed if necessary when the base member 57 is to be released from the base member 61.

### 4. Assembly of Control Apparatus 1

An assembly process of the control apparatus 1 will be described with reference to FIGS. 3, 5, 6, and the like. First, the base member 67 for fixing various components is installed on the bottom surface panel 5D. The base member 67 is formed in a gate shape, for example, and is fixed to the bottom surface panel 5D with screws or the like. Next, various electric components, such as the breaker 23, the electromagnetic switches 25, the hub 27, the power source unit 29, and the second control unit 33, which are disposed in the above-described lower space, are installed on the bottom surface panel 5D. Next, various components constituting the air duct 43, for example, the base member 57, 59, 61, the first chamber 45, the cooling fan 41, and the like are installed on the base member 67. Next, the heat sink 53 on which the servo unit 35 is mounted is installed on the base member 57. Next, the support plate 37 on which the first control unit 31 is mounted is installed on the base member 67 via the base member 65. Thus, the assembly of the internal components of the control apparatus 1 is completed.

Next, the frame 3 is assembled. In detail, the left side frame portion 3L and the right side frame portion 3R are installed at four corners of the bottom surface panel 5D, and the upper end of the left side frame portion 3L and the upper end of the right side frame portion 3R are connected by the front side frame portion 3F and the back side frame portion 3B. Next, the circulation fan 39 is installed at the rear ends of the left side frame portion 3L and the right side frame portion 3R and the back side frame portion 3B. Next, various electric components are connected and wired by cables, lead wires, and the like. Each panel 5 is then installed in the frame 3. The order of installation of the panels 5 is not particularly limited, but for example, the back surface panel 5B, the left surface panel 5L, and the right panel 5R may be installed first, the front surface panel 5F may be installed next, and the upper surface panel 5U may be installed last.

As described above, the structure in which the respective parts are assembled upward with the bottom surface panel 5D as a reference and the frame 3 and the panel 5 are assembled after the completion of the assembly of the internal parts is adopted, whereby automation of the assembly process can be promoted. For example, the assembly process may be performed by an automatic machine such as a robot until the internal components are assembled, and the subsequent assembly of the frame 3 and the panel 5 and wiring may be performed manually. The assembly of the frame 3 and the panel 5 except for the wiring may be automated, and the wiring may also be automated.

### 5. Effects of Embodiment

As described above, the control apparatus 1 of the present embodiment includes the first chamber 45, the second chamber 47, and the third chamber 49. The air flowing into the first chamber 45 from the outside is passed through the second chamber 47 and the third chamber 49 in this order. Since the opening cross-sectional area S2 of the second chamber 47 is smaller than the opening cross-sectional area S1 of the first chamber 45, the air speed of the air sucked from the outside in the first chamber 45 can be increased to ventilate the second chamber 47. Further, since the opening cross-sectional area S3 of the third chamber 49 is smaller than the opening cross-sectional area S2 of the second chamber 47, the air speed of the air flowing through the second chamber 47 can be further increased to pass through the third chamber 49. In this way, the wind speed can be increased in stages, and thus the cooling efficiency can be increased. Further, by changing the opening cross-sectional area in each of the first chamber 45, the second chamber 47, and the third chamber 49, the air duct 43 can be configured such that the opening cross-sectional area decreases toward the downstream side in the airflow direction. This eliminates the need to provide a dedicated member for forming an air passage such as a duct having a flow path that is narrowed toward the downstream side, and thus the control apparatus 1 can be downsized. Therefore, according to the embodiment, it is possible to realize the control apparatus 1 capable of improving the cooling efficiency and being miniaturized.

In the present embodiment, the air may be passed through the second chamber 47 communicating with the first chamber 45 to cool the components to be cooled, and the air that has cooled the components may be discharged to the outside in the third chamber 49 communicating with the second chamber 47. Since the opening cross-sectional area S2 of the second chamber 47 is smaller than the opening cross-sectional area S1 of the first chamber 45, the air speed of the air flowing in from the outside in the first chamber 45 can be increased to ventilate the second chamber 47. Further, since the opening cross-sectional area S3 of the third chamber 49 is smaller than the opening cross-sectional area S2 of the second chamber 47, the air flowing through the second chamber 47 can be exhausted at an increased speed. The wind speed in the second chamber 47 can be further increased by the pulling action from the downstream side due to the increase in the wind speed of the exhaust gas. This can increase the cooling efficiency in the second chamber 47.

In the present embodiment, the first chamber 45 may include a first intake port 45A and a first exhaust port 45B, and the second chamber 47 may include a second intake port 47A and a second exhaust port 47B. Since the opening cross-sectional area S5 of the second intake port 47A is smaller than the opening cross-sectional area S4 of the first intake port 45A, the air sucked from the first intake port 45A can be sucked from the second intake port 47A while increasing the wind velocity. Further, since the opening cross-sectional area S6 of the second exhaust port 47B is smaller than the opening cross-sectional area S5 of the second intake port 47A, the air sucked from the second intake port 47A can be discharged from the second exhaust port 47B at an increased speed. This can increase the wind speed in the second chamber 47, and thus the cooling efficiency in the second chamber 47 can be enhanced.

In the present embodiment, the third chamber 49 may include a third intake port 49A and a third exhaust port 49B. Since the opening cross-sectional area S7 of the third exhaust port 49B is smaller than the opening cross-sectional area S6 of the third intake port 49A, the air sucked from the third intake port 49A can be discharged to the outside from the third exhaust port 49B while increasing the wind velocity. The wind speed in the second chamber 47 can be further increased by the pulling action due to the increase in the wind speed of the exhaust gas in the third chamber 49, and thus the cooling efficiency in the second chamber 47 can be enhanced.

In the present embodiment, the cooling fan 41 may be installed in the first chamber 45 and may be arranged to be inclined by a predetermined angle θ with respect to a direction D2 perpendicular to the left surface panel 5L so that the rotation axis direction D1 of the cooling fans 41 faces the second intake port 47A. In this case, the air discharged from the cooling fan 41 can be directed to the second air intake 45A having a smaller opening cross-sectional area than the first air intake 47A, and thus the air resistance of the air duct 43 can be reduced, and the air sucked from the outside can be efficiently passed through the second chamber 47.

In the present embodiment, the first intake port 45A may be provided in the left surface panel 5L of the housing 2, and the third exhaust port 49B may be provided in the back surface panel 5B. For example, in a case where the first intake port 45A is provided in the left surface panel 5L of the housing 2 and the third exhaust port 49B is provided in the right surface panel 5R, when the control apparatus 1 is arranged side by side in the left-right direction, the air discharged from the control apparatus 1 is sucked by the adjacent control apparatus 1, and the cooling effect is reduced. In the present embodiment, the above configuration allows the control apparatus 1 to be arranged side by side in the left-right direction without reducing the cooling efficiency. Further, thermal interference with a device disposed adjacent to the control apparatus 1 on the right side can be suppressed.

In the present embodiment, the first air intake 45A and the third air outlet 49B may be provided in the panels 5L and 5B adjacent to each other at substantially right angles in the substantially rectangular parallelepiped housing 2. That is, the substantially L-shaped air duct 43 may be formed inside the control apparatus 1. Thus, the control apparatus 1 can be arranged side by side without reducing the cooling efficiency. Further, thermal interference with a device disposed adjacent to the right side of the control apparatus 1 can be suppressed. In the present embodiment, the air duct 43 may be formed by a plurality of base members 57, 59, 61 that support the electrical components in the second chamber 47. In this case, the base member 57, 59, 61 having a function of supporting the electric components can be used for forming the air duct 43. Therefore, it is not necessary to provide a dedicated member for forming an air passage such as a duct, and thus the control apparatus 1 can be downsized.

In the present embodiment, the second chamber 47 may house the fin 53a of the heat sink 53 and the regenerative resistor 55 which are disposed to face each other, and a space sandwiched between the fin 53a and the regenerative resistor 55 may form the air duct 43. In this case, the components to be cooled accommodated in the second chamber 47 can be used to form the air duct 43. Therefore, it is not necessary to provide a dedicated member for forming an air passage such as a duct, and thus the control apparatus 1 can be downsized.

In the present embodiment, the control apparatus 1 may include the circulation fan 39 that is disposed in the internal space of the housing 2 other than the first chamber 45, the second chamber 47, and the third chamber 49 and circulates the air in the internal space. In this case, the heat accumulated in the internal space of the housing 2 other than the first chamber 45, the second chamber 47, and the third chamber 49 can be circulated, dispersed, and cooled. Further, since the space cooled by using the outside air and the space in which the inside air is circulated can be separated from each other, the cooling efficiency in each space can be improved.

In the present embodiment, electrical components mounted in a portion other than the air duct 43 may be disposed in the internal space of the housing 2 other than the air duct 43 (the first chamber 45, the second chamber 47, and the third chamber 49). In this case, the electric components mounted in the portion other than the air duct 43 can be cooled.

In the present embodiment, the housing 2 may have a panel structure in which a plurality of panels 5 corresponding to the respective directions are assembled to the frame 3. In this case, the panel 5 is removed only in a necessary direction, and thus the inside of the housing 2 can be accessed from any direction without removing the entire housing 2. The frame 3 may be a divided structure composed of a plurality of parts. In this case, the installation space during transportation or the like can be saved.

In the above description, when there is a description such as “perpendicular”, “parallel”, or “planar”, the description does not have a strict meaning. The terms “perpendicular”, “parallel”, and “planar” mean “substantially perpendicular”, “substantially parallel”, and “substantially planar”, respectively, with design and manufacturing tolerances and errors being allowed.

In the above description, when there is a description such as “same”, “similar”, “equal”, or “different” in terms of the dimension, size, shape, position, or the like in appearance, the description does not have a strict meaning. The terms “same”, “similar”, “equal”, and “different” mean “substantially same”, “substantially similar”, “substantially equal”, and “substantially different”, respectively, with design and manufacturing tolerances and errors being allowed.

In addition to the above description, the methods according to the above embodiment and the modifications may be appropriately combined and used. In addition, although not illustrated one by one, the above-described embodiment and each modification example are implemented by adding various modifications within a range not departing from the gist thereof.

The problems and effects to be solved by the embodiments, the modifications, and the like described above are not limited to the contents described above. The embodiments and the modifications can solve problems not described above and can produce effects not described above, and may solve only some of the problems described above and can produce only some of the effects described above.

What is claimed is:

1. A control apparatus comprising:
a first chamber into which air is configured to flow from an outside of the control apparatus and which has a cross-sectional area of flow;
a second chamber which communicates with the first chamber such that the air flows from the first chamber to the second chamber and which has a cross-sectional area of flow smaller than the cross-sectional area of flow of the first chamber; and
a third chamber which communicates with the second chamber such that the air flows from the second chamber to the third chamber and which has a cross-sectional area of flow smaller than the cross-sectional area of flow of the second chamber.

2. The control apparatus according to claim 1, further comprising:
a first fan provided in at least one of the first chamber and the third chamber and configured to allow the air to flow into the second chamber from the first chamber,
wherein the second chamber houses a component to be cooled, and
wherein the air is discharged from the third chamber to the outside.

3. The control apparatus according to claim 2,
wherein the first chamber comprises
a first intake port via which the air flows into the first chamber from the outside, and
a first exhaust port via which the air flows out to the second chamber from the first chamber,
wherein the second chamber comprises
a second intake port via which the air flows into the second chamber from the first chamber, and
a second exhaust port via which the air flows out to the third chamber from the second chamber,
wherein the second intake port has a cross-sectional area of flow which is smaller than a cross-sectional area of flow of the first intake port, and
wherein the second exhaust port has a cross-sectional area of flow which is smaller than the cross-sectional area of flow of the second intake port.

4. The control apparatus according to claim 3,
wherein the third chamber comprises
a third intake port via which the air flows into the third chamber from the second chamber, and
a third exhaust port via which the air flows out to the outside from the third chamber,
wherein the third exhaust port includes a cross-sectional area of flow which is smaller than a cross-sectional area of flow of the third intake port.

5. The control apparatus according to claim 1, further comprising:
a housing containing the first chamber, the second chamber, and the third chamber; and
a first fan having a rotation axis and provided in the first chamber to allow the air to flow into the second chamber from the first chamber,
wherein the first chamber comprises
a first intake port via which the air flows into the first chamber from the outside, and
a first exhaust port via which the air flows into the second chamber from the first chamber,
wherein the second chamber comprises
a second intake port via which the air flows into the second chamber from the first chamber,
a second exhaust port via which the air flows into the third chamber from the second chamber, and
wherein the first fan is provided such that a direction of the rotation axis faces toward the second air intake and is inclined at a predetermined angle with respect to a direction perpendicular to a wall portion of the housing where the first air intake is provided.

6. The control apparatus according to claim 1, further comprising:
a housing containing the first chamber, the second chamber, and the third chamber;
wherein the first chamber comprises
a first intake port via which the air flows into the first chamber from the outside, and
a first exhaust port via which the air flows out to the second chamber from the first chamber,
wherein the second chamber comprises
a second intake port via which the air flows into the second chamber from the first chamber, and
a second exhaust port via which the air flows out to the third chamber from the second chamber,
wherein the third chamber comprises
a third intake port via which the air flows into the third chamber from the second chamber, and
a third exhaust port via which the air flows out to the outside from the third chamber, and
wherein the first intake port is provided on a side surface of the housing and the third exhaust port is provided on a back surface of the housing.

7. The control apparatus according to claim 6,
wherein the housing has a substantially rectangular parallelepiped shape, and
wherein the side surface and the back surface of the housing are provided to be adjacent to each other such that the side surface is substantially perpendicular to the back surface.

8. The control apparatus according to claim 1, further comprising:
a plurality of support members provided in the second chamber to support an electric component or electric components, the plurality of support members forming an air duct in the second chamber.

9. The control apparatus according to claim 1,
wherein the second chamber houses one electric component and a fin of a heat sink of another electric component, and the one electric component and the another electric component are provided such that the fin faces the one electric component to form an air duct between the fin and the one electric component.

10. The control apparatus according to claim 1, further comprising:
a housing containing the first chamber, the second chamber, and the third chamber;
a first fan provided in at least one of the first chamber and the third chamber and configured to allow the air to flow into the second chamber from the first chamber, and
a second fan provided in an internal space of the housing other than the first chamber, the second chamber, and the third chamber and configured to circulate air in the internal space.

11. The control apparatus according to claim 10,
wherein an electric component is provided in the internal space.

12. A cooling method of a control apparatus, comprising:
letting air flow from an outside of the control apparatus into a first chamber which has a cross-sectional area of flow;
letting the air flow from the first chamber to a second chamber which has a cross-sectional area of flow smaller than the cross-sectional area of flow of the first chamber; and
letting the air flow from the second chamber to a third chamber which has a cross-sectional area of flow smaller than the cross-sectional area of flow of the second chamber.
